(19) United States
(12) Patent Application Publication
(10) Pub. No.: US 2015/0122321 A1
(43) Pub. Date: May 7, 2015

(54) SOLAR CELL

(71) Applicant: Electronics and Telecommunications Research Institute, Daejeon (KR)

(72) Inventors: JungWook LIM, Daejeon (KR); Kyu Sung LEE, Seoul (KR); Sun Jin YUN, Daejeon (KR)

(73) Assignee: Electronics and Telecommunications Research Institute, Daejeon (KR)

(21) Appl. No.: 14/271,840

(22) Filed: May 7, 2014

(30) Foreign Application Priority Data
Nov. 4, 2013 (KR) 10-2013-0133052

(51) Int. Cl. H01L 31/0368; H01L 31/0216; H01L 31/0376

(52) U.S. Cl. CPC H01L 31/03682; H01L 31/03762; H01L 31/02167
USPC 136/256

(57) ABSTRACT

Provided is a solar cell including a semiconductor substrate having a first conductivity type; a semiconductor layer having a second conductivity type and disposed on one surface of the semiconductor substrate; a passivation layer disposed on the other surface of the semiconductor substrate; a front electrode disposed on the semiconductor layer; and a back electrode disposed on the passivation layer, wherein the passivation layer comprises a plurality of silicon layers having different crystallinity.

### CROSS-REFERENCE TO RELATED APPLICATIONS

This U.S. non-provisional patent application claims priority under 35 U.S.C. §119 of Korean Patent Application No. 10-2013-0133052, filed on Nov. 4, 2013, the entire contents of which are hereby incorporated by reference.

### BACKGROUND OF THE INVENTION

The present invention disclosed herein relates to a solar cell, and more particularly to, a crystalline silicon solar cell.

With the recent interest in new renewable energy, a high-efficiency solar cell is receiving attention. In particular, an abundant material and avirulence silicon based crystalline silicon solar cell has occupied about 90% of the total solar cell market and has made an effort to lower cost.

In the case of the crystalline silicon solar cell, since defects on the surface of the silicon and in the silicon act as sites of recombination of electrons and holes generated by light and as a result decrease the photoelectric conversion of a solar cell, there is a need to effectively passivate the defects.

### SUMMARY OF THE INVENTION

The present invention provides a solar cell that may be implemented at high efficiency.

Tasks to be resolved by the present invention are not limited to the above-described tasks and other tasks that are not mentioned will be able to be recognized by a person skilled in the art from the following description.

Embodiments of the present invention provide solar cells include a semiconductor substrate having a first conductivity type; a semiconductor layer having a second conductivity type and disposed on one surface of the semiconductor substrate; a passivation layer disposed on the other surface of the semiconductor substrate; a front electrode disposed on the semiconductor layer; and a back electrode disposed on the passivation layer, wherein the passivation layer comprises a plurality of silicon layers having different crystallinity.

In some embodiments, the passivation layer may include an interface layer and a capping layer sequentially stacked on the semiconductor substrate, wherein the interface layer may have lower crystallinity than the capping layer.

In other embodiments, the interface layer and the capping layer may include amorphous silicon.

In still other embodiments, at least one of the interface layer and the capping layer may include silicon in which amorphous silicon is mixed with crystalline silicon.

In even other embodiments, at least one of the interface layer and the capping layer may include silicon oxide, silicon nitride, silicon carbide, silicon germanium compound, aluminum oxide, or titanium oxide.

In yet other embodiments, the interface layer may have a greater energy band gap than the capping layer.

In further embodiments, the passivation layer may have a thickness of about 5 nm to about 100 nm.

In still further embodiments, the passivation layer may include an interface layer, an intermediate layer, and a capping layer sequentially stacked on the semiconductor substrate.

In even further embodiments, the interface layer may have lower crystallinity than the capping layer, and the intermediate layer may have lower crystallinity than the interface layer and the capping layer.

In yet further embodiments, the intermediate layer may include amorphous silicon, silicon oxide, silicon nitride, silicon carbide, silicon germanium compound, aluminum oxide, or titanium oxide.

In much further embodiments, the intermediate layer may have a plurality of layers and have crystallinity that increases or decreases gradually from the interface layer toward the capping layer.

In still much further embodiments, at least one of the interface layer, the intermediate layer, and the capping layer may be doped with a dopant.

In even much further embodiments, the dopant may be boron (B), aluminum (Al), gallium (Ga), phosphorous (P), arsenic (As), or nitrogen (N).

In yet much further embodiments, the passivation layer may have a top surface including a protrusion and a recess alternately and repetitively.

In yet much further embodiments, the passivation layer may include an interface layer and a capping layer that are sequentially stacked on the semiconductor substrate, wherein the top surface of the interface layer may have the same shape as the top surface of the passivation layer.

In yet much further embodiments, the passivation layer may have a thickness of about 5 nm to about 100 nm

In yet much further embodiments, the semiconductor substrate may include a single crystal silicon substrate.

In yet much further embodiments, the solar cell may further include an anti-reflective layer between the semiconductor layer and the front electrode.

In yet much further embodiments, the solar cell may further include another passivation layer between the semiconductor layer and the front electrode.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a cross-section view of a solar cell according to a first embodiment of the present invention;

FIG. 2 is a cross-section view of a solar cell according to a second embodiment of the present invention;

FIG. 3 is a cross-section view of a solar cell according to a third embodiment of the present invention;

FIG. 4 is a cross-section view of a solar cell according to a fourth embodiment of the present invention;

FIG. 5 is a cross-section view of a solar cell according to a fifth embodiment of the present invention;

FIG. 6 is a cross-section view of a solar cell according to a sixth embodiment of the present invention;

FIG. 7 is a cross-section view of a solar cell according to a seventh embodiment of the present invention;

FIG. 8 is a cross-section view of a solar cell according to an eighth embodiment of the present invention; and

FIG. 9 is a graph of a result of measuring a charge lifetime vs. a temperature in the following process of the present invention.

### DETAILED DESCRIPTION OF PREFERRED EMBODIMENTS

The effects and features of the present invention, and implementation methods thereof will be clarified through following embodiments described with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Further, the present invention is only defined by scopes of claims. The same reference numerals throughout the disclosure refer to the same components.

The terms used herein are only for explaining specific embodiments while not limiting the present invention. The terms of a singular form may include plural forms unless referred to the contrary. The terms used herein “includes”, “comprises”, “including” and/or “comprising” do not exclude the presence or addition of one or more components, steps, operations and/or elements other than the components, steps, operations and/or elements that are mentioned.

Also, the disclosure will describe embodiments with reference to cross-section views and/or plane views that are ideal exemplary views of the present invention. In the drawings, the thickness of layers and regions is exaggerated for the effective description of the technical content. Thus, the forms of exemplary views may vary by manufacturing technologies and/or tolerances. Thus, embodiments of the present invention are not limited to shown specific forms and also include variations in form produced according to manufacturing processes. For example, an etch region shown as a rectangular shape may have a round shape or a shape having a certain curvature. Thus, regions illustrated in the drawings are exemplary, and the shapes of the regions illustrated in the drawings are intended to illustrate the specific shapes of the regions of elements and not to limit the scope of the present invention.

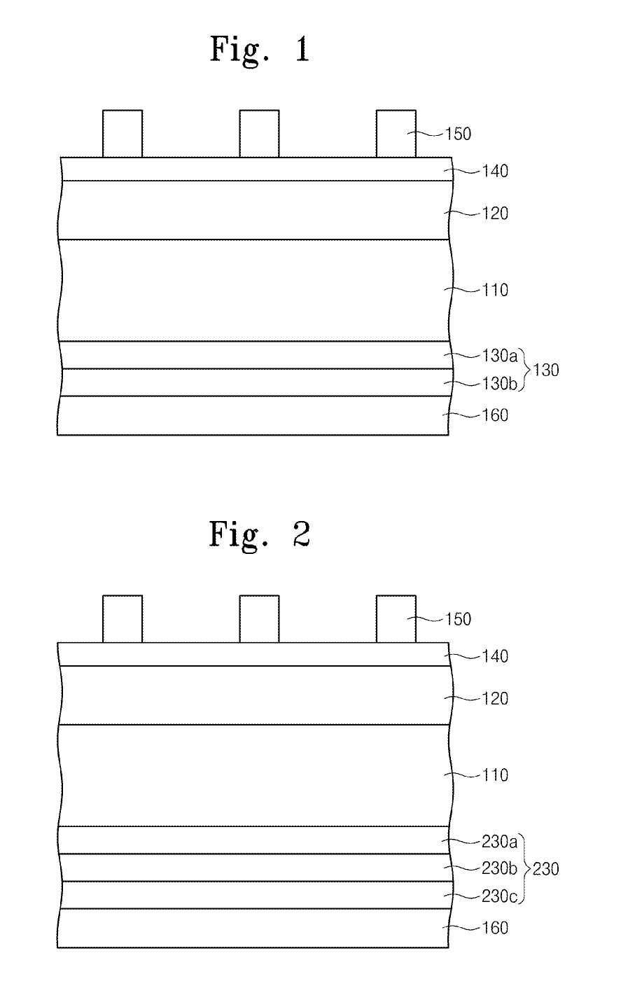

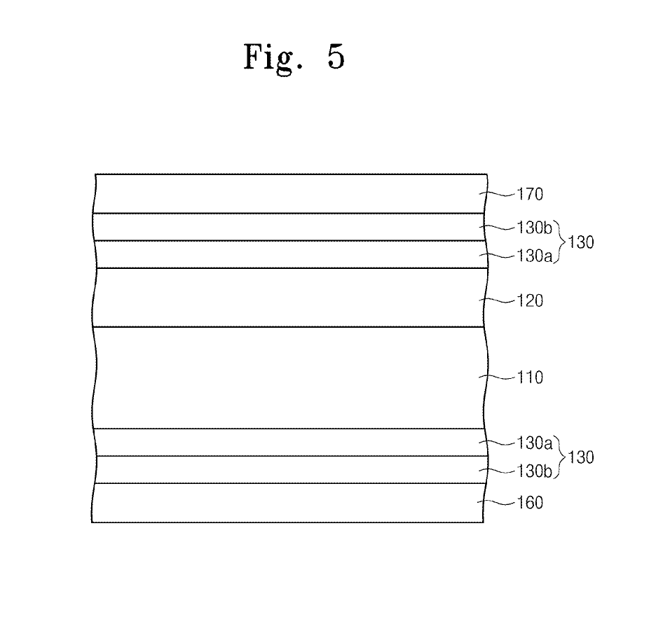

FIG. 1 is a cross-section view of a solar cell according to a first embodiment of the present invention. FIG. 5 is a cross-section view of a solar cell according to a fifth embodiment of the present invention;

Referring to FIG. 1, the solar cell includes a semiconductor substrate 110 of a first conductivity type, a semiconductor layer 120 of a second conductivity type, a passivation layer 130, a front electrode 150, an anti-reflective layer 140, and a back electrode 160.

The semiconductor substrate 110 may be a p-type single crystal silicon substrate. For example, the semiconductor substrate 110 may be doped with III-group elements such as boron (B), gallium (Ga), and Indium (In).

The semiconductor layer 120 is disposed on one surface of the semiconductor substrate 110. The semiconductor layer 120 may be an n-type silicon layer. For example, the semiconductor layer 120 may be an n-type emitter layer that is doped with IV-group elements such as phosphorous (P), arsenic (As), and antimony (Sb). The semiconductor substrate 110 and the semiconductor layer 120 may form a p-n junction.

The passivation layer 130 is disposed on the other surface of the semiconductor substrate 110. The passivation layer 130 may include an interface layer 130a and a capping layer 130b that are sequentially stacked on the semiconductor substrate 110. The interface layer 130a and the capping layer 130b may include the same amorphous silicon. On the other hand, the interface layer 130a and the capping layer 130b may have different crystallinity and different energy band gaps. Specifically, even if they include the same amorphous silicon, they may have different energy band gaps according to a difference in crystallinity. The crystallinity means the degree of structural order in a solid. The crystallinity may be adjusted by controlling the flow ratio of hydrogen and precursor in a chemical vapor deposition process. The interface layer 130a may be amorphous silicon having lower crystallininty than the capping layer 130b. That is, since the capping layer 130b has a micro-crystalline between amorphous and crystalline, it may be amorphous silicon having higher crystallinity than the interface layer 130a. In general, as the crystallinity is low, the energy band gap becomes great. Thus, the interface layer 130a may have a greater energy band gap than the capping layer 130b. The passivation layer 130 may have a thickness of about 5 nm to about 100 nm

On the other hand, the interface layer 130a and/or the capping layer 130b may be a silicon layer in which amorphous silicon is mixed with crystalline silicon.

According to another embodiment, at least one of the interface layer 130a and the capping layer 130b may include silicon oxide (SiOx), silicon nitride (SiNx), silicon carbide (SiCx), silicon germanium compound (SiGe), aluminum oxide (AlOx), or titanium oxide (TiOx).

Since there are many defects (e.g. dangling bonds) at the interface between the semiconductor substrate 110 and the semiconductor layer 120, electron and hole are recombined at the interface between the semiconductor substrate 110 and the semiconductor layer 120. The recombination of the electron-hole pairs causes a problem that decreases the photoelectric conversion of a solar cell. Thus, a plurality of passivation layers 130 may be disposed on the semiconductor substrate 110 to passivate the defects of the interface between the semiconductor substrate 110 and the semiconductor layer 120, so it is possible to prevent electron-hole pairs from becoming recombined. Thus, it is possible to enhance efficiency in photoelectric conversion by enhancing the internal electric field of the solar cell.

In general, an amorphous thin film having low crystallinity has a great energy band gap and is excellent in passivation characteristic of dangling bonds. However, the amorphous thin film having low crystallinity lacks internal density, so defects are formed in the amorphous thin film. In contrast, an amorphous thin film having excellent crystallinity is excellent in internal density, so it has much less defects. However, in the case of the amorphous thin film having excellent crystallinity, as the thickness of the thin film increases, the thin film is easily deformed to a crystalline thin film at a high temperature. Thus, there may be defects (or dangling bonds) between the amorphous thin film having the excellent crystallinity and the silicon substrate. Thus, the capping layer 130b is formed along with the interface layer 130a to be able to decrease a thickness, so it is possible to minimize the deformation of the capping layer 130b to the crystalline thin film. Also, the capping layer 130b prevents damages to the interface layer 130a in a high-temperature process, so it is possible to maintain the passivation characteristic between the semiconductor substrate 110 and the interface layer 130a. Thus, since the open voltage of the solar cell is enhanced and its internal electric field is increased, the present invention may have an effect that increases charge collection.

The anti-reflective layer 140 may be disposed on the semiconductor layer 120. The anti-reflective layer 140 may be formed to lower reflectivity to sunlight. The anti-reflective layer 140 may be a single layer including e.g., silicon nitride layer, a silicon nitride layer containing hydrogen, a silicon oxide layer, a silicon oxynitride layer, or any one of MgF₂, ZnS, MgF₂, TiO, and CeO₂, or multiple layers including two or more material layers in structure.

The front electrode 150 may be disposed on the anti-reflective layer 140. The front electrode 150 may be patterned to expose a portion of the surface of the anti-reflective layer 140. The front electrode 150 may be electrically coupled to the semiconductor layer 120. The front electrode 150 may be a transparent electrode that has a great energy band gap. The front electrode 150 may be e.g., a metal including silver (Ag) or a transparent conductive material that has a great energy band gap.

The back electrode 160 may be disposed on the passivation layer 130. The back electrode 160 may be electrically coupled to the semiconductor substrate 110. The back electrode 160 may include e.g., aluminum (Al).

Referring to FIG. 5, the passivation layer 130 and a transparent front electrode 170 may be sequentially stacked on the semiconductor layer 120. The passivation layer 130 may function as the anti-reflective layer 140. The transparent front electrode 170 may be formed to completely cover the top surface of the capping layer 130b. The back electrode 160 may be a transparent conductive material.

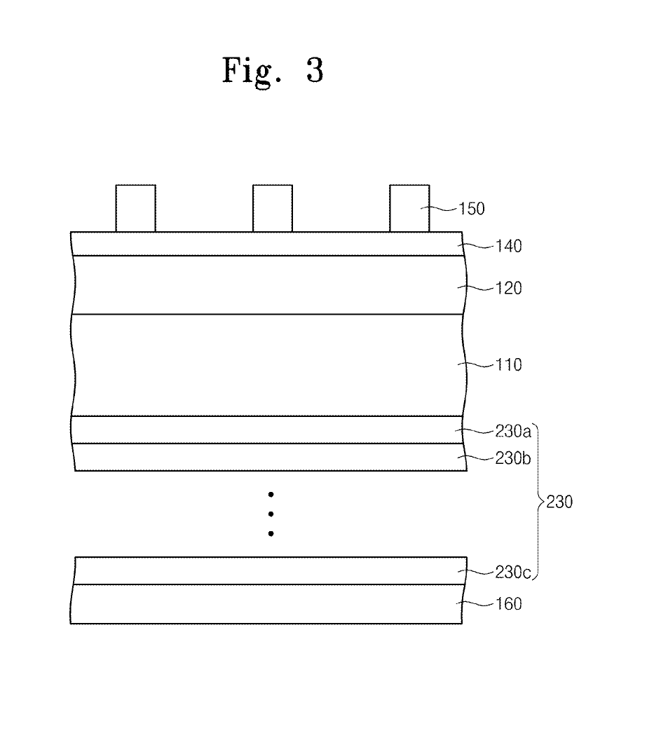

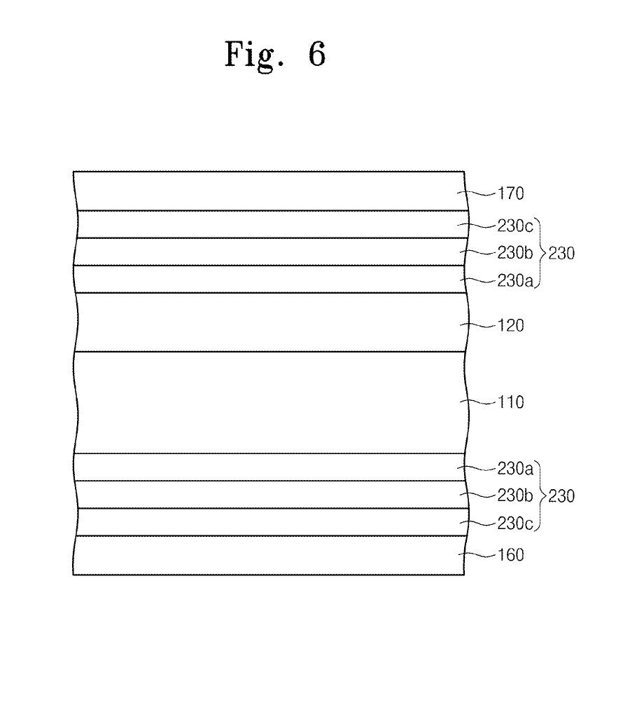

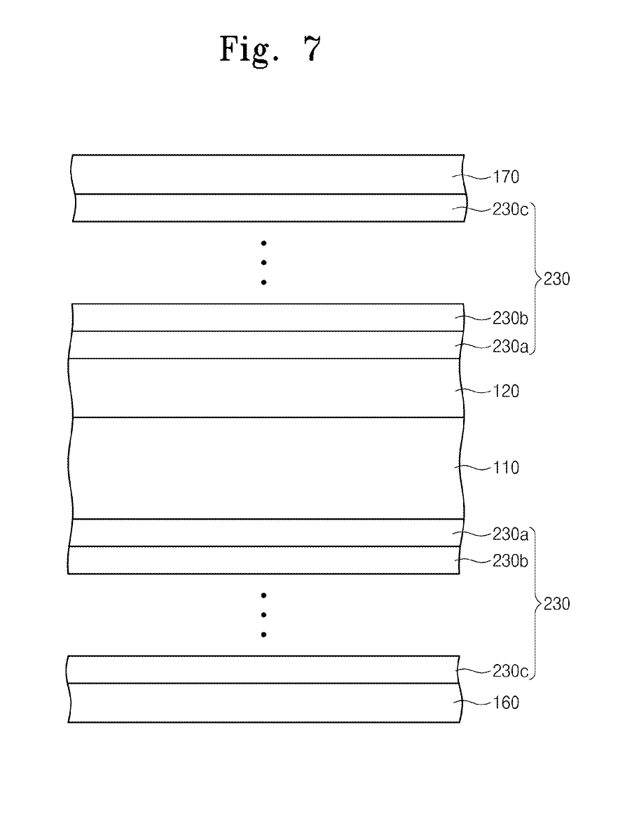

FIG. 2 is a cross-section view of a solar cell according to a second embodiment of the present invention. FIG. 3 is a cross-section view of a solar cell according to a third embodiment of the present invention. FIG. 6 is a cross-section view of a solar cell according to a sixth embodiment of the present invention. FIG. 7 is a cross-section view of a solar cell according to a seventh embodiment of the present invention. Descriptions of the technical characteristics described above with reference to FIGS. 1 and 5 are not repeated.

Referring to FIG. 2, a passivation layer 230 may further include an intermediate layer 230b between an interface layer 230a and a capping layer 230c. The intermediate layer 230b may include amorphous silicon having lower crystallinity than the interface layer 230a and the capping layer 230c, silicon oxide, silicon nitride, silicon carbide, silicon germanium compound, aluminum oxide (AlOx), or titanium oxide (TiOx). If the intermediate layer 230b is formed to have lower crystallininty than the interface layer 230a and the capping layer 230c, it is possible to have better electrical characteristics.

Referring to FIG. 6, the passivation layer 230 and the transparent front electrode 170 may be sequentially formed on the semiconductor layer 120.

Referring to FIG. 3, a plurality of intermediate layers 230b may be disposed between the interface layer 230a and the capping layer 230c. The intermediate layers 230b have lower crystallininty than the interface layer 230a and the capping layer 230c and may have gradually varying crystallinity. For example, the crystallinity of the intermediates 230b may increase or decrease from the interface layer 230a toward the capping layer 230c.

When forming the passivation layers 230 in a triple or more layer structure, it is possible to stably maintain or increase charge lifetime when a high temperature is needed to form the back electrode 160. In addition, when the intermediate layer 230c is formed as a thin film having low crystallinity, it may raise thermal stability and obtain higher values in charge lifetime and open voltage as compared to when the passivation layer has double layers or a single layer.

In some embodiments, any one of the interface layer 230a, the intermediate layer 230b, and the capping layer 130c may be doped with a dopant. For example, the dopant may be doped only on the interface layer 230a, and the dopant may be doped on both the intermediate layer 230a and the intermediate layer 230b. The dopant may be a III-group element (e.g., boron (B), aluminum (Al), gallium (Ga)) or a V-group element (e.g., phosphorous (P), arsenic (As), nitrogen (N)). When the dopant is doped on the passivation layer 230, charge lifetime increases and the open voltage of the solar cell may be enhanced.

Referring to FIG. 7, the passivation layer 230 and the transparent front electrode 170 may be sequentially disposed on the semiconductor layer 120.

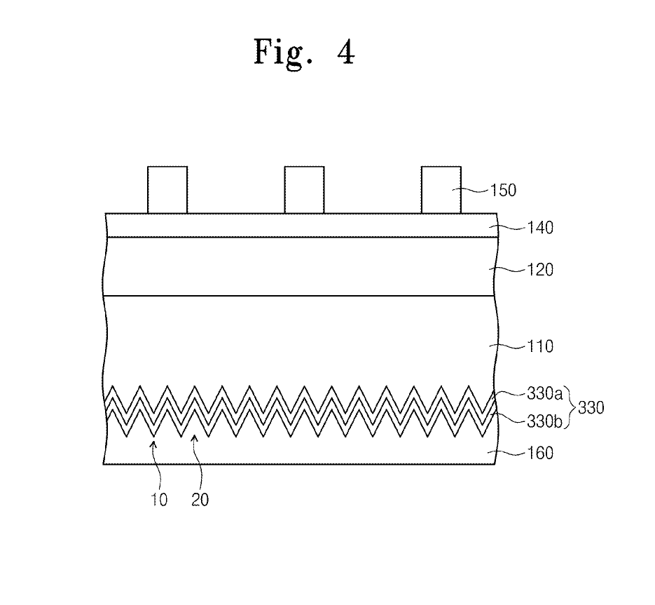

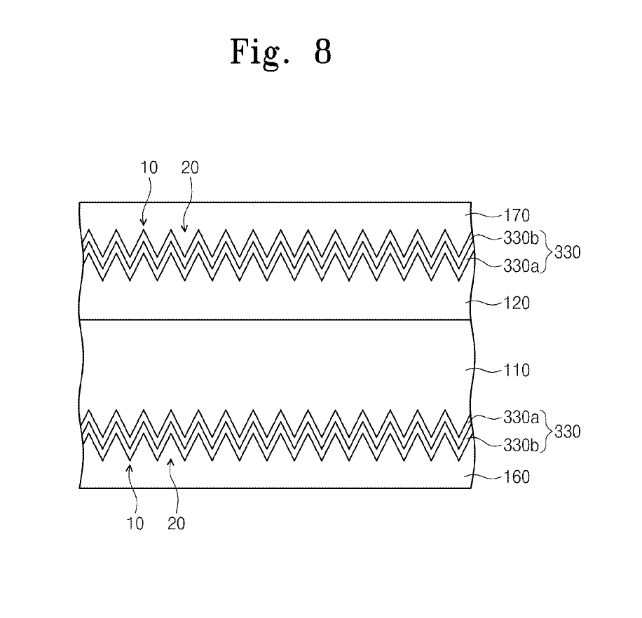

FIG. 4 is a cross-section view of a solar cell according to a fourth embodiment of the present invention. FIG. 8 is a cross-section view of a solar cell according to an eighth embodiment of the present invention. Descriptions of the technical characteristics described above with reference to FIGS. 1 and 5 are not repeated.

Referring to FIG. 4, the passivation layer 330 may have a top surface that has a protrusion 10 and a recess 20 alternately and repetitively. Specifically, the bottom surface of the semiconductor substrate 110 may be formed to have the protrusion 10 and the recess 20 by an etch process or patterning, and the passivation layer 330 formed on the semiconductor substrate 100 may be formed to have the same profile as the bottom surface of the semiconductor substrate 100. The passivation layer 330 may include an interface layer 330a and a capping layer 330b that are sequentially stacked on the semiconductor substrate 110. Thus, the top surfaces of the interface layer 330a and the capping layer 330b may have the same surface as the bottom of the semiconductor substrate 110. The passivation layer 330 may have a thickness of about 5 nm to about 100 nm.

Referring to FIG. 8, the passivation layer 330 and the transparent front electrode 170 may be sequentially formed on the semiconductor layer 120. The semiconductor layer 120 has a top surface that has the protrusion 10 and the recess 20 alternatively and repetitively. And, the interface layer 330a and the capping layer 330b sequentially formed on the semiconductor layer 120 have a surface having the same profile as the top surface of the semiconductor layer 200. The transparent front electrode 170 may be formed to completely cover the capping layer 330b.

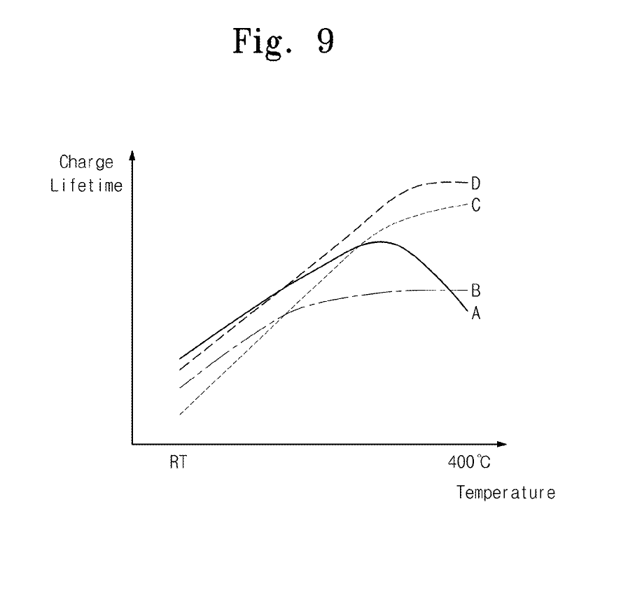

FIG. 9 is a graph of a result of measuring a charge lifetime vs. a temperature in the following process of the present invention.

Referring to FIG. 9, curve A corresponds to an interface layer having high crystallinity or represents when the thickness of the interface layer is 20 nm or more. Curve B represents when a passivation layer has a single layer. Curves C and

D represent when the passivation layer has multiple layers.

As a result, when forming the back electrode 160 requiring a high temperature, it is possible to stably form the back electrode 160 without a decrease in charge lifetime at the high temperature when the passivation layer has multiple layers (curves C and D).

For the solar cell according to embodiments of the present invention, a plurality of passivation layers are disposed on the semiconductor layer. The passivation layers passivate defects in the interface between the semiconductor substrate and the semiconductor layer, so it is possible to prevent electron-hole pairs from becoming recombined.

In addition, the passivation layers may stably maintain or increase charge lifetime, when a high temperature is needed to form the back electrode in the following process.

While embodiments of the present invention are described with reference to the accompanying drawings, a person skilled in the art will be able to understand that the present invention may be practiced as other particular forms without changing essential characteristics. Therefore, embodiments described above should be understood as illustrative and not limitative in every aspect.

What is claimed is:

1. A solar cell comprising:
a semiconductor substrate having a first conductivity type;
a semiconductor layer having a second conductivity type and disposed on one surface of the semiconductor substrate;
a passivation layer disposed on the other surface of the semiconductor substrate;
a front electrode disposed on the semiconductor layer; and
a back electrode disposed on the passivation layer, wherein the passivation layer comprises a plurality of silicon layers having different crystallinity.

2. The solar cell of claim 1, wherein the passivation layer comprises an interface layer and a capping layer sequentially stacked on the semiconductor substrate, wherein the interface layer has lower crystallinity than the capping layer.

3. The solar cell of claim 2, wherein the interface layer and the capping layer comprise amorphous silicon.

4. The solar cell of claim 2, wherein at least one of the interface layer and the capping layer comprises silicon in which amorphous silicon is mixed with crystalline silicon.

5. The solar cell of claim 2, wherein at least one of the interface layer and the capping layer comprises silicon oxide, silicon nitride, silicon carbide, silicon germanium compound, aluminum oxide, or titanium oxide.

6. The solar cell of claim 2, wherein the interface layer has a greater energy band gap than the capping layer.

7. The solar cell of claim 1, wherein the passivation layer has a thickness of about 5 nm to about 100 nm.

8. The solar cell of claim 1, wherein the passivation layer comprises an interface layer, an intermediate layer, and a capping layer sequentially stacked on the semiconductor substrate.

9. The solar cell of claim 8, wherein the interface layer has lower crystallinity than the capping layer, and the intermediate layer has lower crystallinity than the interface layer and the capping layer.

10. The solar cell of claim 9, wherein the intermediate layer comprises amorphous silicon, silicon oxide, silicon nitride, silicon carbide, silicon germanium compound, aluminum oxide, or titanium oxide.

11. The solar cell of claim 8, wherein the intermediate layer has a plurality of layers and has crystallinity that increases or decreases gradually from the interface layer toward the capping layer.

12. The solar cell of claim 8, wherein at least one of the interface layer, the intermediate layer, and the capping layer is doped with a dopant.

13. The solar cell of claim 12, wherein the dopant is boron (B), aluminum (Al), gallium (Ga), phosphorous (P), arsenic (As), or nitrogen (N).

14. The solar cell of claim 1, wherein the passivation layer has a top surface including a protrusion and a recess alternately and repetitively.

15. The solar cell of claim 14, wherein the passivation layer comprises an interface layer and a capping layer that are sequentially stacked on the semiconductor substrate, wherein the top surface of the interface layer has the same shape as the top surface of the passivation layer.

16. The solar cell of claim 14, wherein the passivation layer has a thickness of about 5 nm to about 100 nm.

17. The solar cell of claim 1, wherein the semiconductor substrate comprises a single crystal silicon substrate.

18. The solar cell of claim 1, further comprising an anti-reflective layer between the semiconductor layer and the front electrode.

19. The solar cell of claim 1, further comprising another passivation layer between the semiconductor layer and the front electrode.
